(19) United States
(12) Patent Application Publication
(10) Pub. No.: US 2026/0082797 A1
(43) Pub. Date: Mar. 19, 2026

(54) Electronic Device

(71) Applicant: Innolux Corporation, Miaoli County (TW)

(72) Inventors: Yuan-Lin WU, Miaoli County (TW); Kuan-Feng LEE, Miaoli County (TW)

(73) Assignee: Innolux Corporation, Miaoli County (TW)

(21) Appl. No.: 18/808,074

(22) Filed: Aug. 18, 2024

(30) Foreign Application Priority Data
Sep. 27, 2023 (CN) 202311263331.X

(51) Int. Cl. H10K 59/80; H10H 29/30; H10H 29/85; H10H 29/855; H10K 59/12; H10K 59/38; H10K 59/40; H10K 77/10

(52) U.S. Cl. CPC H10K 59/8792; H10H 29/30; H10H 29/8508; H10H 29/8517; H10H 29/8552; H10K 59/12; H10K 59/38; H10K 59/40; H10K 77/111

(57) ABSTRACT

An electronic device including a substrate, an insulation layer, a first organic portion, a shielding structure, and a first optical unit is provided. The insulation layer is disposed on the substrate and includes a first opening. The first organic portion is disposed in the first opening of the insulation layer. The shielding structure is disposed on the insulation layer and includes a retaining wall and a first opening. The first optical unit is disposed in the first opening of the shielding structure. The retaining wall of the shielding structure overlaps with the first opening of the insulation layer.

### CROSS-REFERENCE TO RELATED APPLICATION

This application claims the priority benefit of China application serial no. 202311263331.X, filed on Sep. 27, 2023. The entirety of the above-mentioned patent application is hereby incorporated by reference herein and made a part of this specification.

### BACKGROUND

### Technical Field

The disclosure relates to an electronic device, and particularly relates to a flexible display device.

### Description of Related Art

When a flexible electronic device is bent, an external anti-reflection layer is prone to peel off. In order to prevent the above phenomenon, an anti-reflection layer is formed within the flexible electronic device (for example, by forming a filter unit or forming an anti-reflection organic layer). However, after the flexible electronic device is bent, an inorganic film layer therein easily produces cracks extending in one direction due to the influence of the bending stress, which reduces the reliability of the flexible electronic device. Additionally, the display surface of the flexible electronic device is prone to problems such as color mixing and/or contrast due to repeated bending and/or process deviation.

### SUMMARY

The embodiments of the disclosure are directed to an electronic device that has relatively good reliability and/or relatively good display effects.

An electronic device according to some embodiments of the disclosure includes a substrate, an insulation layer, a first organic portion, a shielding structure, and a first optical unit. The insulation layer is disposed on the substrate and includes a first opening. The first organic portion is disposed in the first opening of the insulation layer. The shielding structure is disposed on the insulation layer and includes a retaining wall and a first opening. The first optical unit is disposed in the first opening of the shielding structure. The retaining wall of the shielding structure overlaps with the first opening of the insulation layer.

Embodiments are provided below and described in details with reference to accompanying drawings to make features and advantages of the disclosure more obvious and comprehensive.

### BRIEF DESCRIPTION OF THE DRAWINGS

FIG. 1A is a partial top schematic view of an electronic device according to an embodiment of the disclosure.

FIG. 1B is a partial cross-sectional schematic view of a first embodiment according to a cross-section line A-A′ of FIG. 1A.

FIG. 2 is a partial cross-sectional schematic view of a second embodiment according to a cross-section line A-A′ of FIG. 1A.

FIG. 3A is a partial cross-sectional schematic view of a third embodiment according to a cross-section line A-A′ of FIG. 1A.

FIG. 3B is a partial cross-sectional schematic view of a fourth embodiment according to a cross-section line A-A′ of FIG. 1A.

FIG. 4 is a partial cross-sectional schematic view of a fifth embodiment according to a cross-section line A-A′ of FIG. 1A.

FIG. 5 is a partial cross-sectional schematic view of a sixth embodiment according to a cross-section line A-A′ of FIG. 1A.

FIG. 6 shows a partial cross-sectional schematic view of an embodiment of a peripheral area of an electronic device 10f of FIG. 5.

FIG. 7A is a three-dimensional schematic view of an electronic device according to an embodiment of the disclosure.

FIG. 7B is a partially enlarged top schematic view of an embodiment in a region R1 of FIG. 7A.

FIG. 8A shows a three-dimensional schematic view of an electronic device in FIG. 7A after the electronic device is folded.

FIG. 8B is a partially enlarged top schematic view of an embodiment in a region R2 of FIG. 8A.

FIG. 9A is a partial top schematic view of an arrangement relationship between a sensing structure and a first opening of an insulation layer in an electronic device according to an embodiment of the disclosure.

FIG. 9B is a partial top schematic view of an arrangement relationship between a sensing structure, a first opening of an insulation layer, and an optical unit in an electronic device according to a first embodiment of the disclosure.

FIG. 10A is a partial top schematic view of an arrangement relationship between a sensing structure, a first opening of an insulation layer, and an optical unit in an electronic device according to a second embodiment of the disclosure.

FIG. 10B is a partial top schematic view of an arrangement relationship between a sensing structure, a first opening of an insulation layer, and an optical unit in an electronic device according to a third embodiment of the disclosure.

FIG. 10C is a partial top schematic view of an arrangement relationship between a sensing structure, a first opening of an insulation layer, and an optical unit in an electronic device according to a fourth embodiment of the disclosure.

### DETAILED DESCRIPTION OF DISCLOSED EMBODIMENTS

Detailed reference will be made to the exemplary embodiments of the present invention, examples of which are illustrated in the accompanying drawings. The same reference numerals are used in the drawings and descriptions to refer to the same or similar parts.

The disclosure can be understood by referring to the following detailed description with the accompanying drawings. It should be understood that, in order to make the content of the disclosure easier to understand, the drawings in the disclosure will only depict part of an electronic device, and specific elements in the drawings are not drawn to actual scale. In addition, the number and size of elements in the drawings are only for illustration and are not intended to limit the scope of the disclosure.

It should be understood that, specific terms may be used throughout the specification and appended claims to refer to specific elements. The terms used herein have the same meaning as that commonly understood by one of ordinary skill in the art to which this disclosure belong. The disclosure does not intend to differentiate between elements with identical functionality but different terms. In the following specification and claims, terms such as “comprising”, “containing”, and “having” are open-ended terms, so the terms should be interpreted as meaning “including but not limited to . . . ”. Therefore, when the terms “comprising”, “containing”, and/or “having” are used in the description of the disclosure, the terms specify the presence of a corresponding feature, region, step, operation, and/or component, but do not exclude the presence of one or more corresponding features, regions, steps, operations, and/or components.

The directional terms used herein, such as “up”, “down”, “front”, “back”, “left”, “right”, etc., are only for reference to the directions in the accompanying drawings. Accordingly, the directional terms are illustrative, and the disclosure is not limited to these terms. It should be understood that in the accompanying drawings, each drawing illustrates the general features of methods, structures, and/or materials used in particular embodiments. However, these drawings should not be interpreted as defining or limiting the scope or nature encompassed by these embodiments. For example, for clarity, the relative sizes, thicknesses, and locations of various layers, regions, and/or structures may be reduced or enlarged.

When a corresponding component (such as a layer or a region) is referred to as being “on another component”, the component may be directly on the other component, or other components may be present between these two components. Otherwise, when a component is referred to as being “directly on” another component, there are no intervening components unless otherwise stated in the specification. In addition, when a component is referred to as being “on another component”, it means that the two components have a vertical relationship in the top view direction, and the component may be above or below the other component, and the vertical relationship depends on the orientation of the device.

The terms “equal to” or “the same”, “substantially”, or “roughly” are generally interpreted to mean within 20% of a given value or range, or to mean within 10%, 5%, 3%, 2%, 1%, or 0.5% of the given value or range.

The ordinal numbers used in the specification and the claims, such as “first”, “second”, etc., are used to modify elements, and do not imply and represent that the element (or elements) has any previous ordinal number, nor do they represent the order of one element and another element or the order of a manufacturing method. The use of these ordinal numbers is only used to clearly distinguish an element with a certain name from another element with an identical name. The same words may not be used in the claims and the description. Accordingly, a first component in the specification may be a second component in the claims.

It should be noted that for the following embodiments, features of several different embodiments can be replaced, reorganized, and mixed to complete other embodiments without departing from the spirit of the disclosure. The features in the embodiments may be mixed and matched as long as they do not violate the spirit of the invention or conflict with each other.

The electrical-related connection or electrical connection described in the disclosure can refer to a direct connection or an indirect connection. In the case of the direct connection, the end points of the elements on the two circuits are directly connected or connected to each other with a conductor line segment, and in the case of the indirect connection, there are switches, diodes, capacitors, inductors, other suitable elements, or a combination of the above elements between the end points of the elements on the two circuits, but are not limited thereto.

In the disclosure, the thickness, length, width, and area can be measured using an optical microscope, and the thickness can be measured using cross-sectional images in an electron microscope, but are not limited thereto. In addition, any two values or directions used for comparison may have certain errors. If a first value is equal to a second value, it implies that there may be an error of about 10% between the first value and the second value; if a first direction is perpendicular to a second direction, an angle between the first direction and the second direction may be between 80 degrees and 100 degrees; and if the first direction is parallel to the second direction, the angle between the first direction and the second direction may be between 0 degrees and 10 degrees.

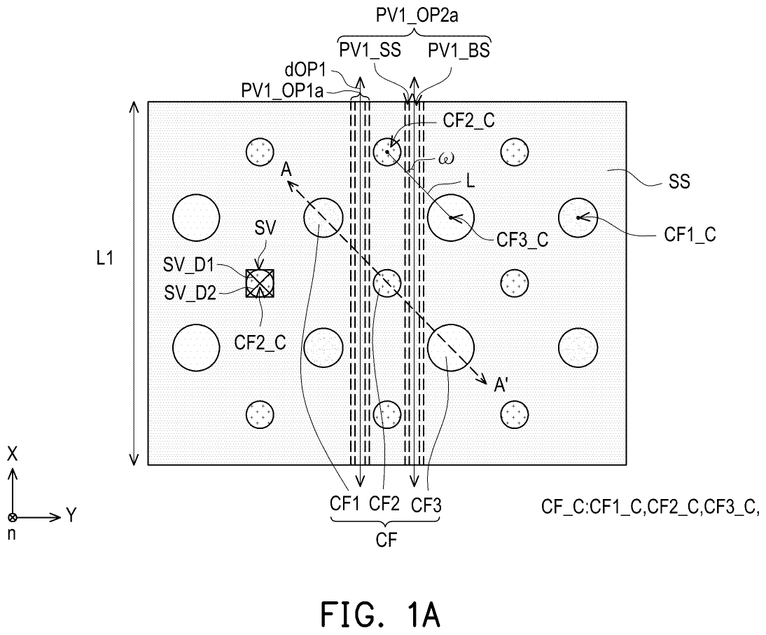

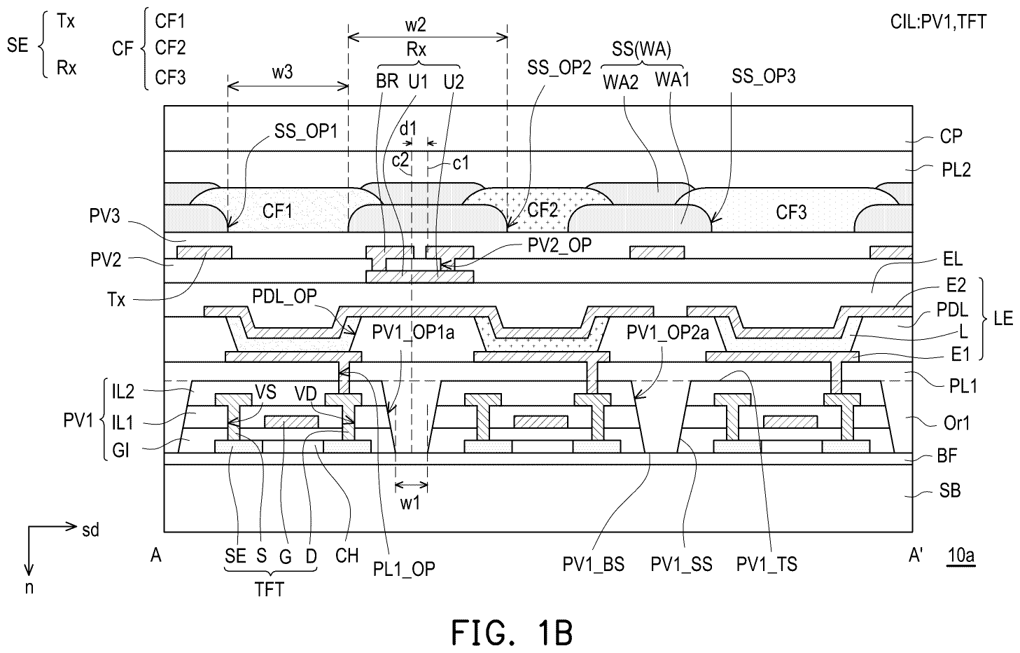

FIG. 1A is a partial top schematic view of an electronic device according to an embodiment of the disclosure, and FIG. 1B is a partial cross-sectional schematic view of a first embodiment according to a cross-section line A-A′ of FIG. 1A.

Referring to FIG. 1A and FIG. 1B simultaneously, an electronic device 10a of the embodiment includes a substrate SB, an insulation layer PV1, a first organic portion Or1, a shielding structure SS, and a first optical unit CF1. In the embodiment, the electronic device 10a may be a display device including a touch function, but the disclosure is not limited thereto. In some embodiments, the electronic device 10a may further include a buffer layer BF, a circuit structure CIL, a planar layer PL1, a light-emitting structure LE, an encapsulation layer EL, a sensing structure SE, the shielding structure SS, an optical unit CF, a planar layer PL2, and a cover plate CP, but the disclosure is not limited hereto. In some embodiments, the sensing structure SE may be used to sense a finger of a user, a stylus, and suitable external objects, but the disclosure is not limited thereto.

The substrate SB may include, for example, a flexible substrate, wherein the material of the substrate SB may include, for example, plastic. For example, the substrate SB may include polymethyl methacrylate (PMMA), polycarbonate (PC), polyimide (PI), polyethylene terephthalate (PET), other suitable materials, or a combination of the above materials.

The buffer layer BF is, for example, disposed on the substrate SB. The buffer layer BF may, for example, have relatively good bonding properties with subsequent film layers formed thereon, but the disclosure is not limited thereto. The material of the buffer layer BF may be, for example, an inorganic material (for example, silicon oxide, silicon nitride, silicon oxynitride, or a stacked layer of at least two of the above materials). In some embodiments, the buffer layer BF may have a single-layer structure or a multi-layer structure, but the disclosure is not limited thereto.

The circuit structure CIL is, for example, disposed on the substrate SB. In this embodiment, the circuit structure CIL is disposed on the buffer layer BF and may include the insulation layer PV1 and a transistor TFT, but the disclosure is not limited thereto.

The insulation layer PV1 is, for example, disposed on the substrate SB. In this embodiment, the insulation layer PV1 may have a multi-layer structure and may be used to separate different conductive layers in the transistor TFT. Specifically, the insulation layer PV1 may include an insulation layer GI, an insulation layer IL1, and an insulation layer IL2, wherein the insulation layer GI is disposed between a semiconductor layer SE and a gate G of the transistor TFT, the insulation layer IL1 is disposed between a source S (or a drain D) and the gate G of the transistor TFT, and the insulation layer IL2 covers the source S and the drain D of the transistor TFT. The material of the insulation layer PV1 may be, for example, an inorganic material (such as silicon oxide, silicon nitride, silicon oxynitride, or a stacked layer of at least two of the above materials), but the disclosure is not limited thereto.

In this embodiment, the insulation layer PV1 includes multiple first openings PV1_OP1a. The outline of the first opening PV1_OP1a of the insulation layer PV1 is, for example, defined by a side surface of the insulation layer IL2, a side surface of the insulation layer IL1, a side surface of the insulation layer GI, and a top surface of the buffer layer BF, wherein the side surface of the insulation layer IL2 is connected to the side surface of the insulation layer IL1, the side surface of the insulation layer IL1 is connected to the side surface of the insulation layer GI, and the side surface of the insulation layer GI is connected to the top surface of the buffer layer BF, but the disclosure not limited thereto. In some embodiments, the outline of the first opening PV1_OP1a of the insulation layer PV1 is in the shape of an inverted trapezoid in the cross-sectional view of the electronic device 10a, but the disclosure is not limited thereto. In this embodiment, the first opening PV1_OP1a of the insulation layer PV1 has a width w1 in a direction sd, wherein the width w1 may be defined as the width of a lower bottom part of the first opening PV1_OP1a of the insulation layer PV1, but the disclosure is not limited thereto. The direction sd is, for example, parallel to a surface defined by a direction X and a direction Y (an X-Y plane), and may, for example, be parallel to a line connecting centers CF_C (including centers CF1_C, CF2_C, and CF3_C) of adjacent optical units CF (including the first optical unit CF1, a second optical unit CF2, and a third optical unit CF3). For example, the direction sd may be parallel to a line L connecting the center CF2_C of the second optical unit CF2 and the center CF3_C of the third optical unit CF3, but the disclosure is not limited thereto.

The outline of the first opening PV1_OP1a of the insulation layer PV1 may be defined, for example, by a side wall PV1_SS and a lower bottom surface PV1_BS, wherein when the width w1 is defined as the width of the lower bottom part of the first opening PV1_OP1a of the insulation layer PV1, the width w1is also the width of the lower bottom surface PV1_BS in the direction sd, but the disclosure is not limited thereto. In other embodiments, when the width w1 is defined as the width of an upper bottom part of the first opening PV1_OP1a of the insulation layer PV1, the width w1is the width between two intersection points of an upper bottom surface PV1_TS (shown in FIG. 1B) of the insulation layer PV1 and the side wall PV1_SS in the direction sd. In other words, regardless of the top view or the cross section, the width, length, and distance are measured on the same basis.

The center CF_C of the optical unit CF is, for example, defined by a smallest virtual rectangle SV that may surround the optical unit CF, wherein an intersection point of two diagonals SV_D1 and SV_D2 of the smallest virtual rectangle SV is the center CF_C of the optical unit CF. For example, FIG. 1A shows that the intersection point of the diagonal line SV_D1 and the diagonal line SV_D2 of the smallest virtual rectangle SV surrounding the second optical unit CF2 is the center CF2_C of the second optical unit CF2. In some embodiments, the width w1 of the first opening PV1_OP1a of the insulation layer PV1 complies with the following relationship: 0.1 μm≤w1≤15 μm.

In this embodiment, the first opening PV1_OP1a may have a length L1 in an extension direction dOP1 thereof, wherein the extension direction dOP1 of the first opening PV1_OP1a is defined by the long side direction of the smallest first opening PV1_OP1a in the top view shown in FIG. 1A. In some embodiments, the extension direction dOP1 of the first opening PV1_OP1a may be parallel to the direction X, but the disclosure is not limited thereto. In some embodiments, the length L1 and the width w1 of the first opening PV1_OP1a of the insulation layer PV1 may comply with the following relationship: L1/w1>2, wherein the length L1 of the first opening PV1_OP1a is defined by the long side direction of the smallest first opening PV1_OP1a in the top view shown in FIG. 1A, and the smallest width of the first opening PV1_OP1a is defined by the short side direction of the smallest first opening PV1_OP1a in the top view shown in FIG. 1A. For example, the ratio of the length L1 to the width w1 of the first opening PV1_OP1a of the insulation layer PV1 may be greater than 2, greater than 10, or greater than 1000, but the disclosure is not limited thereto. In addition, when the opening in the top view is not a long straight line, the smallest virtual rectangle may be used to surround the opening, the long side direction of the enclosed smallest virtual rectangle is used to define the extension direction, and the smallest virtual rectangle may also be used to define the length, that is, the width of the opening.

In addition, in this embodiment, the insulation layer PV1 may also include a second opening PV1_OP2a adjacent to the first opening PV1_OP1a, wherein the outline of the second opening PV1_OP2a of the insulation layer PV1 may be the same as or similar to the outline of the first opening PV1_OP1a of the insulation layer PV1, but the disclosure is not limited thereto. In other embodiments, the outline of the second opening PV1_OP2a of the insulation layer PV1 may be different from the outline of the first opening PV1_OP1a of the insulation layer PV1.

Consequently, when one or more of the insulation layers in the insulation layer PV1 cracks due to factors such as being bent, the first opening PV1_OP1a and/or the second opening PV1_OP2a of the insulation layer PV1 may block the extension path of the crack, thereby reducing the possibility of the transistor TFT being invaded by external moisture.

The transistor TFT may, for example, include the gate G, the source S, the drain D, and the semiconductor layer SE, but the disclosure is not limited thereto. The gate G, for example, partially overlaps with the semiconductor layer SE in a top view direction n of the substrate SB, wherein a region where the semiconductor layer SE overlaps with the gate G may be regarded as a channel region CH, and the semiconductor layer SE may have a source region and a drain region located on opposite sides of the channel region CH. The source S and the drain D are, for example, separated from each other and are respectively electrically connected to the semiconductor layer SE. In some embodiments, the material of the semiconductor layer SE may include amorphous silicon, low-temperature polycrystalline silicon (LTPS), metal oxide, other suitable materials, or a combination thereof (for example, a combination of low-temperature polycrystalline silicon and metal oxide, that is, low-temperature polycrystalline oxide (LTPO)), wherein the metal oxide may include indium gallium zinc oxide (IGZO). In this embodiment, the material of the semiconductor layer SE includes low-temperature polycrystalline silicon, but the disclosure is not limited thereto. In this embodiment, the source S and the drain D may be respectively electrically connected to the source region and the drain region of the semiconductor layer SE through a hole VS and a hole VD that penetrate the insulation layer IL1 and the insulation layer GI, but the disclosure is not limited thereto. The transistor TFT of this embodiment is, for example, a top gate type thin film transistor. However, although this embodiment takes the top gate thin film transistor as an example, the disclosure is not limited thereto.

The planar layer PL1 is, for example, disposed on the substrate SB and partially covers the circuit structure CIL. From another perspective, the planar layer PL1 may, for example, include an opening PL1_OP that exposes a part of the drain D of the transistor TFT. The material of the planar layer PL1 may be, for example, an organic material (such as polytetrafluoroethylene, polyimide, parylene, benzocyclobutene, or other suitable materials), but the disclosure is not limited thereto. In this embodiment, the planar layer PL1 may have a relatively flat top surface, so that a film layer subsequently formed thereon have a relatively good yield. In this embodiment, the planar layer PL1 includes a first organic portion Or1. The first organic portion Or1 is, for example, disposed in the first opening PV1_OP1a of the insulation layer PV1.

In this embodiment, by disposing the first organic portion Or1 in the first opening PV1_OP1a of the insulation layer PV1, a relatively flat top surface can be provided above the first opening PV1_OP1a, and the first opening PV1_OP1a filled with the first organic portion Or1 can have a more stable structure, so that the film layer subsequently formed thereon has a relatively good yield.

The light-emitting structure LE is, for example, disposed on the planar layer PL1. In some embodiments, the light-emitting structure LE includes a first electrode E1, a light-emitting layer L, a second electrode E2, and a pixel definition layer PDL.

The first electrode E1 is, for example, disposed on the planar layer PL1 and is electrically connected to the drain D of the transistor TFT, for example, through the opening PL1_OP of the planar layer PL1. In some embodiments, the first electrode E1 may be used as an anode of the light-emitting structure LE and/or a pixel electrode of the transistor TFT, but the disclosure is not limited thereto. The material of the first electrode E1 may include metal, metal oxide, other suitable materials, or a combination thereof, but the disclosure is not limited thereto.

The light-emitting layer L is, for example, disposed on the first electrode E1. In some embodiments, the light-emitting layer L may, for example, include a suitable structure and a material thereof. For example, the light-emitting layer L may include an organic material, but the disclosure is not limited thereto.

The second electrode E2 is, for example, disposed on the first electrode E1. In some embodiments, the second electrode E2 may be used as a cathode of the light-emitting structure LE, but the disclosure is not limited thereto. The material of the second electrode E2 may include metal, metal oxide, other suitable materials, or a combination thereof, but the disclosure is not limited thereto.

The pixel definition layer PDL is, for example, disposed on the planar layer PL1. In this embodiment, the pixel definition layer PDL partially covers the first electrode E1. From another perspective, the pixel definition layer PDL includes, for example, an opening PDL_OP that exposes a part of the first electrode E1, wherein the light-emitting layer L may, for example, be disposed in the opening PDL_OP, but the disclosure is not limited thereto. The pixel definition layer PDL may include, for example, a transparent material or a light-shielding material, but the disclosure is not limited thereto. In this embodiment, the opening PDL_OP of the pixel definition layer PDL does not overlap with the first opening PV1_OP1a of the insulation layer PV1, which can reduce the possibility of optical problems such as uneven brightness caused by the first opening PV1_OP1a of the insulation layer PV1.

The encapsulation layer EL is, for example, disposed on the light-emitting structure LE. In this embodiment, the encapsulation layer EL covers the light-emitting structure LE. In some embodiments, the encapsulation layer EL may have a single-layer structure or a multi-layer structure, but the disclosure is not limited thereto. The material of the encapsulation layer EL may be, for example, an inorganic material (such as silicon oxide, silicon nitride, silicon oxynitride, or a stacked layer of at least two of the above materials), an organic material (such as polytetrafluoroethylene, polyimide, polyimide, parylene, benzocyclobutene, or other suitable materials), or a combination of the above, but the disclosure is not limited thereto. For example, the encapsulation layer EL may be a stacked structure of inorganic material/organic material/inorganic material, but the disclosure is not limited thereto. In this embodiment, the encapsulation layer EL may have a relatively flat top surface similar to the planar layer PL, so that a subsequent film layer formed thereon has a relatively good yield.

The sensing structure SE is, for example, disposed on the insulation layer PV1 and partially overlaps with the first opening PV1_OP1a of the insulation layer PV1. In this embodiment, the sensing structure SE is disposed on the encapsulation layer EL and includes a first unit U1, a second unit U2, and a bridging portion BR. The first unit U1 and the second unit U2 are, for example, disposed on the encapsulation layer EL. In this embodiment, the first unit U1, the second unit U2, and the bridging portion BR may be, for example, sensing electrodes Rx of the sensing structure SE. Specifically, a conductive layer in the sensing structure SE may include a sensing electrode Rx and a driving electrode Tx, wherein the sensing electrode Rx and the driving electrode Tx may, for example, have a rhombic shape and/or a metal mesh shape in the top view direction of the substrate SB1, but the disclosure is not limited thereto. An insulation layer PV2 is, for example, disposed on the encapsulation layer EL and has an opening PV2_OP that exposes the first unit U1 and the second unit U2. The bridging portion BR is, for example, disposed on the insulation layer PV2 and is connected to the first unit U1 and the second unit U2. In this embodiment, the bridging portion BR belongs to different layers from the first unit U1 and the second unit U2, and may be electrically connected to the first unit U1 and the second unit U2 through the opening PV2_OP penetrating the insulation layer PV2. An insulation layer PV3 is, for example, disposed on the insulation layer PV2 and covers the bridging portion BR. In some embodiments, the materials of the sensing electrode Rx and the driving electrode Tx may include transparent conductive materials or metal materials, and the materials of the insulation layer PV2 and the insulation layer PV3 may include inorganic materials (for example: silicon oxide, silicon nitride, silicon oxynitride, or stacked layers of at least two of the above materials), but the disclosure is not limited thereto.

The shielding structure SS is, for example, disposed on the insulation layer PV1 and includes, for example, a retaining wall WA and a first opening SS_OP1. In this embodiment, the shielding structure SS is disposed on the sensing structure SE, wherein the first opening SS_OP1 of the shielding structure SS may expose a part of the insulation layer PV3 of the sensing structure SE. In some embodiments, the shielding structure SS may further include a second opening SS_OP2 and a third opening SS_OP3, wherein the second opening SS_OP2 and the third opening SS_OP3 of the shielding structure SS may also expose parts of the insulation layer PV3 of the sensing structure SE. The retaining wall WA is, for example, disposed between the first opening SS_OP1 and the second opening SS_OP2 of the shielding structure SS and/or between the second opening SS_OP2 and the third opening SS_OP3 of the shielding structure SS. In some embodiments, the retaining wall WA may include a multi-layer structure. In this embodiment, the retaining wall WA may include a stacked structure formed by a first sub-layer WA1 and a second sub-layer WA2, but the disclosure is not limited thereto. The retaining wall WA may, for example, have a width w2 in the direction sd, wherein the width w2 may, for example, be defined as the maximum width of one of the first sub-layer WA1 and the second sub-layer WA2 in the direction sd, but the disclosure is not limited thereto. The direction sd is, for example, parallel to the surface defined by the direction X and the direction Y of the substrate SB (the X-Y plane). In this embodiment, the width w2 of the retaining wall WA is the width of the first sub-layer WA1 in the direction sd, but the disclosure is not limited thereto. In some embodiments, the shielding structure SS may include a light-shielding material. For example, the material of the shielding structure SS may include black resin or a metal material with low reflectivity, but the disclosure is not limited thereto.

In some embodiments, the width w2 of the retaining wall WA of the shielding structure SS complies with the following relationship: 8 μm≤w2≤15 μm. In this embodiment, the width w2 of the retaining wall WA of the shielding structure SS may be greater than or equal to the width w1 of the first opening PV1_OP1a of the insulation layer PV1. In other words, the width w2 of the retaining wall WA of the shielding structure SS and the width w1 of the first opening PV1_OP1a of the insulation layer PV1 comply with the following relationship: w1≤w2. In some embodiments, the width w2 of the retaining wall WA of the shielding structure SS and the width w1 of the first opening PV1_OP1a of the insulation layer PV1 satisfy the following relationship: 1≤w2/w1≤150.

In this embodiment, the retaining wall WA of the shielding structure SS overlaps with the first opening PV1_OP1a of the insulation layer PV1. Specifically, a part with the maximum width (the first sub-layer WA1) in the retaining wall WA of the shielding structure SS overlaps with the first opening PV1_OP1a of the insulation layer PV1 in the top view direction n of the substrate SB. Consequently, when the electronic device 10a is operating, uneven brightness, dark lines, and/or other optical defects that may be caused by the formation of the first opening PV1_OP1a of the insulation layer PV1 can be shielded by the shielding structure SS, so that the electronic device 10a of this embodiment can achieve good display effects. In addition, in this embodiment, the retaining wall WA of the shielding structure SS also overlaps with the second opening PV1_OP2a of the insulation layer PV1, which can also achieve the above effects. It is worth noting that although this embodiment shows that the shielding structure SS overlaps with the corresponding first opening PV1_OP1a of the insulation layer PV1, the disclosure is not limited thereto.

In this embodiment, there may be a distance d1 between a center line c1 of the first opening SS_OP1 of the shielding structure SS and a center line c2 of the first opening PV1_OP1a of the insulation layer PV1, wherein the center line c1 of the first opening SS_OP1 of the shielding structure SS is a line passing through a bottom center of the first opening SS_OP1, and the center line c2 of the first opening PV1_OP1a of the insulation layer PV1 is a line passing through a bottom center of the first opening PV1_OP1a. Alternatively, in the cross-sectional view, the center line c1 of the first opening SS_OP1 of the shielding structure SS is a line passing through a smallest width center of the first opening SS_OP1, and the center line c2 of the first opening PV1_OP1a of the insulation layer PV1 is a line passing through a smallest width center of the first opening PV1_OP1a. In some embodiments, the distance d1 satisfies the following relationship: 0 μm≤d1≤10 μm.

The optical unit CF is, for example, disposed on the sensing structure SE. In some embodiments, the optical unit CF may have light filtering, wavelength conversion, and/or other optical functions, but the disclosure is not limited thereto. In this embodiment, the optical unit CF includes the first optical unit CF1. The first optical unit CF1 is, for example, disposed in the first opening SS_OP1 of the shielding structure SS. In some embodiments, the first optical unit CF1 may include a red filter pattern, a green filter pattern, or a blue filter pattern, but the disclosure is not limited thereto. In this embodiment, the optical unit CF also includes the second optical unit CF2 and the third optical unit CF3. The second optical unit CF2 is, for example, disposed in the second opening SS_OP2 of the shielding structure SS, and the third optical unit CF3 is, for example, disposed in the third opening SS_OP3 of the shielding structure SS. In some embodiments, the optical functions included in the first optical unit CF1, the second optical unit CF2, and the third optical unit CF3 may be different from each other, but the disclosure is not limited thereto.

In this embodiment, the first optical unit CF1, the second optical unit CF2, and the third optical unit CF3 may partially overlap with the first sub-layer WA1 of the retaining wall WA, and the second sub-layer WA2 of the retaining wall WA may partially overlap with the optical unit CF1, the second optical unit CF2, and the third optical unit CF3, but the disclosure is not limited thereto.

In some embodiments, a width w3 of the first optical unit CF1 may comply with the following relationship: 10 μm≤w3≤20 μm, but the disclosure is not limited thereto.

In this embodiment, the width w3 of the first optical unit CF1 is greater than or equal to the width w1 of the first opening PV1_OP1a of the insulation layer PV1. Specifically, the first optical unit CF1 may, for example, have the width w3 in the direction sd, wherein the width w3 is the width of a part of the first optical unit CF1 that does not overlap with the shielding structure SS in the top view direction n of the substrate SB. In some embodiments, the width w3 of the first optical unit CF1 and the width w1 of the first opening PV1_OP1 of the insulation layer PV1 satisfy the following relationship: 1<w3/w1≤200. When the width w3 and the width w1 satisfy the above relationship, the shielding structure SS can have a relatively good anti-reflection effect. Specifically, when w3/w1≤1, the width w1 of the first opening PV1_OP1a of the insulation layer PV1 is greater than the width w3 of the first optical unit CF1, which causes depression in the first optical unit CF1 and/or the shielding structure SS that affects the anti-reflection effect of the shielding structure SS. In addition, when w3/w1>200, the width w1 of the first opening PV1_OP1a of the insulation layer PV1 is too small, which may cause the insulation layer PV1 to not have the effect of reducing stress (such as bending stress).

In some embodiments, in a top view of the electronic device 10a, an included angle @ between a line connecting the centers of adjacent optical units on both sides of the first opening PV1_OP1a of the insulation layer PV1 (for example, the line L connecting the center CF2_C of the second optical unit CF2 and the center CF3_C of the third optical unit CF3) and the extension direction dOP1 of the first opening PV1_OP1a is greater than or equal to 30° to less than or equal to 50°, but the disclosure is not limited thereto. It is worth noting that the included angle @ is exemplified by an acute angle formed by the line L connecting the center CF2_C of the second optical unit CF2 and the center CF3_C of the third optical unit CF3 and the extension direction dOP1 of the first opening PV1_OP1a.

The planar layer PL2 is, for example, disposed on the insulation layer PV3 and overlaps with the shielding structure SS and the optical unit CF. The material of the planar layer PL2 may be, for example, an organic material (such as polytetrafluoroethylene, polyimide, parylene, benzocyclobutene, or other suitable materials), but the disclosure is not limited thereto.

The cover plate CP may be, for example, disposed on the planar layer PL2. The material of the cover plate CP may include, for example, glass, plastic, or a combination thereof. In this embodiment, the material of the cover plate CP includes plastic, glass, or a combination thereof, but the disclosure is not limited thereto.

In this embodiment, the shielding structure SS may serve as an anti-reflection layer of the electronic device 10a. Consequently, compared with the structure in which the anti-reflection layer is externally attached to the cover plate CP, the electronic device 10a of this embodiment can reduce the stress of the electronic device 10a when bent by arranging the shielding structure SS on the insulation layer PV3 inside the electronic device 10a, and the reliability of the electronic device 10a can also be improved. Specifically, when the electronic device 10a is bent, by combining the design of arranging the shielding structure SS inside the electronic device 10a and the design of the first opening PV1_OP1a of the insulation layer PV1, the stress of the electronic device 10a when bent can be reduced, and because the shielding structure SS may not be easily peeled off from the insulation layer PV3, the reliability of the electronic device 10a can be improved.

The electronic device 10a of this embodiment may be, for example, formed by performing the following process. However, it should be noted that the manufacturing method of the electronic device of the disclosure is not limited thereto.
Step (1) of providing the substrate SB is performed. The material of the substrate SB may be, for example, referred to the above embodiment and will not be further described.
Step (2) of forming the circuit structure CIL and the first opening PV1_OP1a of the insulation layer PV1 is performed.

In some embodiments, the circuit structure CIL may be formed on the substrate SB by performing the following steps, but the disclosure is not limited thereto.

In Step (a), the buffer layer BF is formed on the substrate SB. The buffer layer BF may be formed, for example, by a chemical vapor deposition method or other suitable processes on the substrate SB, but the disclosure is not limited thereto.

In Step (b), the semiconductor layer SE is formed on the buffer layer BF. The semiconductor layer SE may be formed, for example, by first forming a semiconductor material layer (not shown) on the buffer layer BF using a chemical vapor deposition method or other suitable processes, and then performing a patterning process on the semiconductor material layer, but the disclosure not limited thereto.

In Step (c), the insulation layer GI, the gate G, and the insulation layer IL1 are formed on the buffer layer BF, wherein the insulation layer GI is, for example, disposed on the buffer layer BF, the gate G is, for example, disposed on the insulation layer GI, and the insulation layer IL1 is, for example, disposed on the insulation layer GI and, for example, overlaps with the gate G.

The insulation layer GI may be formed, for example, by first forming a first insulation material layer (not shown) on the buffer layer BF using a chemical vapor deposition method or other suitable processes, and then performing a patterning process on the first insulation material layer to form an opening that exposes a part of the semiconductor layer SE, but the disclosure is not limited thereto.

The gate G may be formed, for example, by first forming a gate material layer (not shown) on the insulation layer GI using a physical vapor deposition method, a metal chemical vapor deposition method, or other suitable processes, and then performing a patterning process on the gate material layer, but the disclosure is not limited thereto.

The insulation layer IL1 may be formed, for example, by first forming a second insulation material layer (not shown) on the first insulation material layer using a chemical vapor deposition method or other suitable processes, and then performing a patterning process on the first insulation material layer and the second insulation material layer. to form the opening VS and the opening VD that expose parts of the semiconductor layer SE.

In Step (d), the source S and the drain D are formed on the insulation layer IL1. The source S and the drain D may be formed, for example, by first forming source and drain material layers (not shown) on the insulation layer IL1 using a physical vapor deposition method, a metal chemical vapor deposition method, or other suitable processes, and then performing a patterning process on the source and drain material layers, but the disclosure is not limited thereto.

In Step (e), the insulation layer IL2 is formed on the source S and the drain D on the insulation layer IL1. The insulation layer IL2 may be formed, for example, by a chemical vapor deposition method or other suitable processes, but the disclosure is not limited thereto. It should be noted that the insulation layer GI, the insulation layer IL1, and the insulation layer IL2 are formed into the insulation layer PV1.

After completing Step (2) above, Step (3) of forming the light-emitting structure LE on the insulation layer IL2 is performed. The light-emitting structure LE may be formed by selecting a suitable process depending on the material included in the light-emitting layer L. For example, the light-emitting structure LE may be formed by performing an evaporation process or mass transfer, but the disclosure is not limited thereto. It is worth noting that before forming the light-emitting structure LE, the planar layer PL1 may be first formed, for example, by a coating process to overlap with the circuit structure CIL, wherein the planar layer PL1 includes the first organic portion Or1, and the first organic portion Or1 is formed in the first opening PV1_OP1a of the insulation layer PV1.
Step (4) of forming the encapsulation layer EL on the light-emitting structure LE is performed. The encapsulation layer EL may be formed, for example, by a chemical vapor deposition method, a coating process, or other suitable processes, but the disclosure is not limited thereto.
Step (5) of forming the sensing structure SE on the planar layer PL2 is performed. The sensing electrode Rx and the driving electrode Tx in the sensing structure SE may be formed, for example, by a sputtering method or other suitable processes, but the disclosure is not limited thereto. In addition, the insulation layer PV2 disposed on the bridging portion BR of the driving electrode Tx and the sensing electrode Rx and the insulation layer PV3 disposed on the first unit U1 and the second unit U2 of the sensing electrode Rx may be formed, for example, by a chemical vapor deposition or other suitable processes, but the disclosure is not limited thereto.
Step (6) of forming the shielding structure SS on the sensing structure SE is performed, wherein the shielding structure SS includes the opening SS_OP1 and the opening SS_OP2. The shielding structure SS may be formed, for example, by a jet printing process, a coating process, or other suitable processes, but the disclosure is not limited thereto.
Step (7) of forming the optical unit CF on the sensing structure SE is performed, wherein the first optical unit CF1 and the second optical unit CF2 in the optical unit CF are respectively disposed in the opening SS_OP1 and the opening SS_OP2 of the shielding structure SS. The optical unit CF may be formed, for example, by a jet printing process, a coating process, or other suitable processes, but the disclosure is not limited thereto.
Step (8) of forming the planar layer PL2 on the shielding structure SS and the optical unit CF is performed. The planar layer PL2 may be formed, for example, by a coating process or other suitable processes, but the disclosure is not limited thereto.
Step (9) of forming the cover plate CP on the planar layer PL2 is performed.

At this point, the manufacturing of the electronic device 10a of this embodiment is completed, but the method of manufacturing the electronic device 10a of the disclosure is not limited thereto.

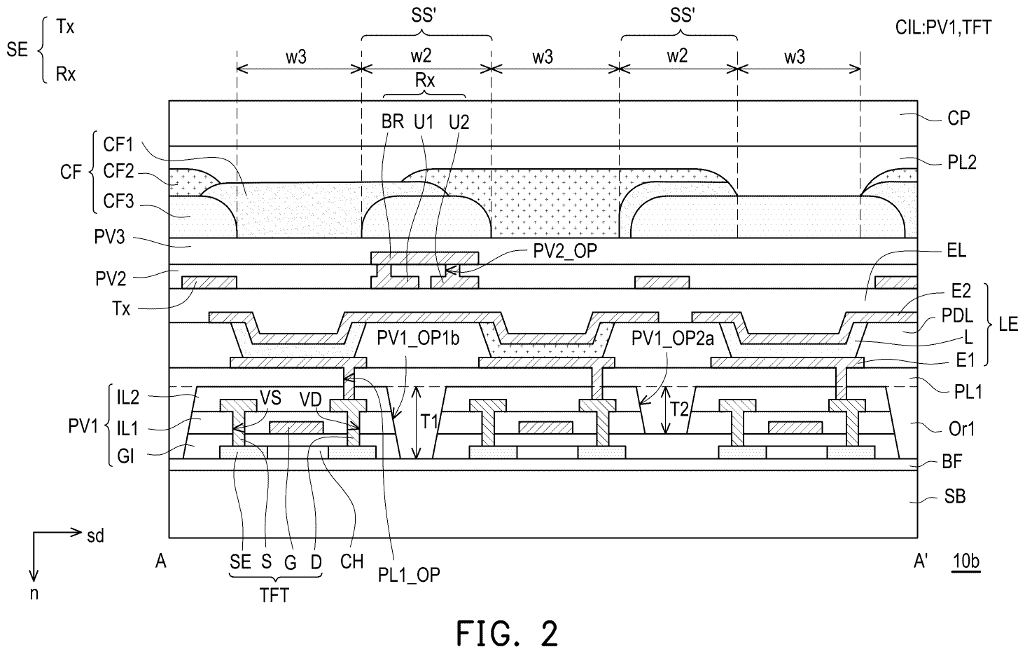

FIG. 2 is a partial cross-sectional view of a second embodiment according to a cross-section line A-A′ of FIG. 1A. It should be noted that the embodiment of FIG. 2 may use the reference numerals and part of the content of the embodiment of FIGS. 1A to 1B, wherein the same or similar numerals are used to represent the same or similar elements, and descriptions of the same technical content are omitted.

Referring to FIG. 2, the main differences between the electronic device 10b of this embodiment and the electronic device 10a are that: (1) a shielding structure SS' is formed by at least two optical units in the optical unit CF; (2) a depth T1 of a first opening PV1_OP1b in the insulation layer PV1 is different from a depth T2 of a second opening PV1_OP2b. In this embodiment, the different designs of the depth T1 of the first opening PV1_OP1b and the depth T2 of the second opening PV1_OP2b can prevent formation of different cracks, for example, due to the stress of bending the electronic device 10b.

In this embodiment, the shielding structure SS' is formed by the overlapping parts of the first optical unit CF1, the second optical unit CF2, and the third optical unit CF3 in the top view direction n of the substrate SB, so that the combination of the shielding structure SS' and the optical unit CF can have light-shielding and/or anti-reflection effects. The shielding structure SS' may, for example, also have the width w2 in the direction sd, wherein the width w2 may be defined as the maximum width of an overlapping portion of the at least two optical units in the direction sd, but the disclosure is not limited thereto. In addition, in this embodiment, the shielding structure SS' also overlaps with the first opening PV1_OP1b of the insulation layer PV1. Specifically, the shielding structure SS' (the overlapping portion of the at least two optical units) overlaps with the first opening PV1_OP1b of the insulation layer PV1 in the top view direction n of the substrate SB.

Consequently, when the electronic device 10b is operating, uneven brightness, dark lines, and/or other optical defects that may be caused by the formation of the first opening PV1_OP1b of the insulation layer PV1 can be shielded by the shielding structure SS′, such that the electronic device 10b can have good display effects.

In this embodiment, the outline of the second opening PV1_OP2b of the insulation layer PV1 is, for example, defined by a side surface of the insulation layer IL2, a side surface of the insulation layer IL1, and a top surface of the insulation layer GI, wherein the side surface of the insulation layer IL2 is connected to the side surface of the insulation layer IL1, and the side surface of the insulation layer IL1 is connected to the top surface of the insulation layer GI. From another perspective, the second opening PV1_OP2b of the insulation layer PV1 exposes a part of the insulation layer GI, and the first opening PV1_OP1b of the insulation layer PV1 exposes a part of the buffer layer BF. Based on this, in this embodiment, the depth T1 of the first opening PV1_OP1b in the insulation layer PV1 may be greater than the depth T2 of the second opening PV1_OP2b, but the disclosure is not limited thereto.

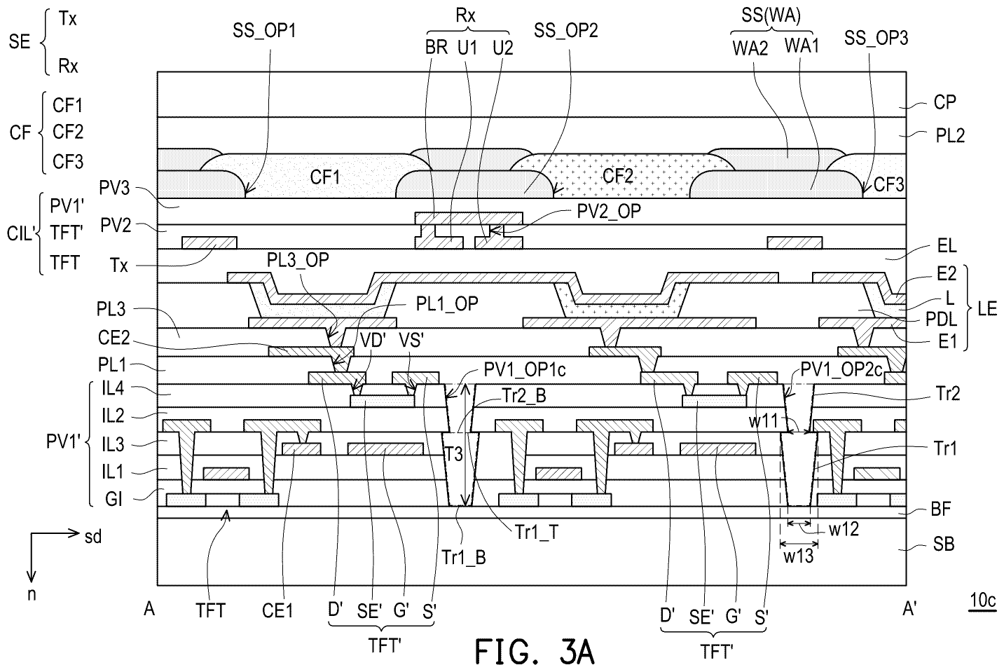

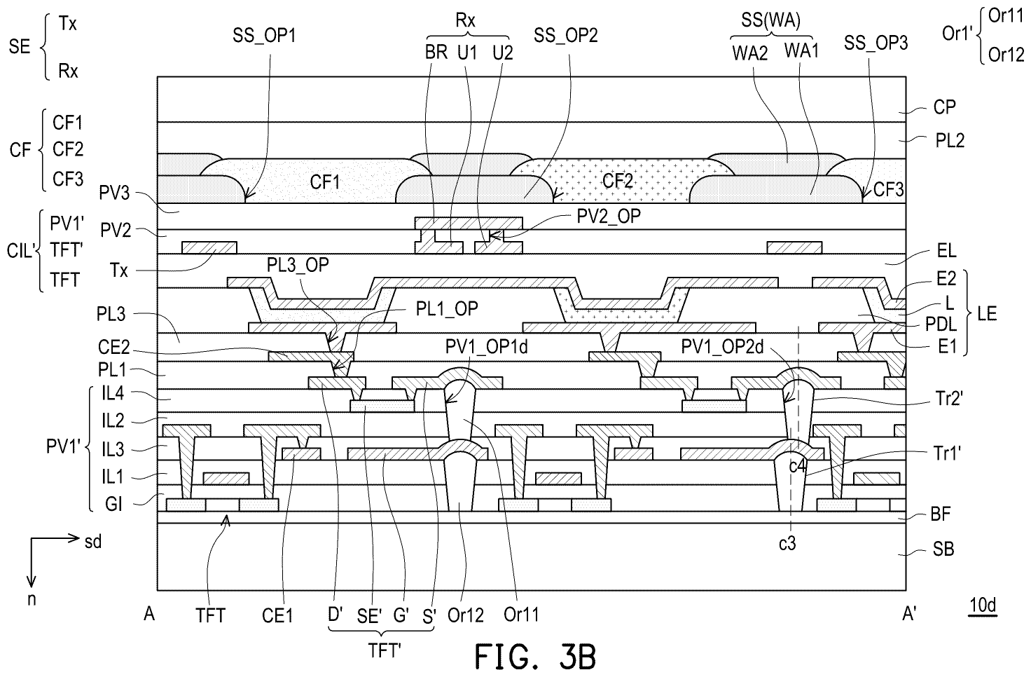

FIG. 3A is a partial cross-sectional schematic view of a third embodiment according to a cross-section line A-A′ of FIG. 1A. It should be noted that the embodiment of FIG. 3A may use the reference numerals and part of the content of the embodiment of FIGS. 1A to 1B, wherein the same or similar numerals are used to represent the same or similar elements, and descriptions of the same technical content are omitted.

Referring to FIG. 3A, the main differences between the electronic device 10c of this embodiment and the electronic device 10a are that: (1) a circuit structure CIL′ also includes a transistor TFT′; and (2) an outline of a first opening PV1_OP1c of an insulation layer PV1′ is in the form of two overlapping inverted trapezoids in the cross-sectional view of the electronic device 10c.

In this embodiment, the circuit structure CIL′ includes the insulation layer PV1′, the transistor TFT of the above embodiment, the transistor TFT′, a connection electrode CE1, a connection electrode CE2, and a planar layer PL3.

Compared with the insulation layer PV1 of the above embodiment, the insulation layer PV1′ further includes an insulation layer IL3 and an insulation layer IL4. In this embodiment, the insulation layer IL3 is disposed between the insulation layer IL1 and the insulation layer IL2 and overlaps with a gate G′ of the transistor TFT′, and the insulation layer ILA is disposed on the insulation layer IL2 and partially overlaps with a semiconductor layer SE′. The materials of the insulation layer IL3 and the insulation layer IL4 may be, for example, inorganic materials (such as silicon oxide, silicon nitride, silicon oxynitride, or stacked layers of at least two of the above materials), but the disclosure is not limited thereto.

The transistor TFT′ may, for example, include the gate G′, a source S′, a drain D′, and the semiconductor layer SE′, but the disclosure is not limited thereto. The gate G′, for example, partially overlaps with the semiconductor layer SE′ in the top view direction n of the substrate SB. The source S′ and the drain D′ are, for example, separated from each other and are respectively electrically connected to the semiconductor layer SE′. In some embodiments, the material of the semiconductor layer SE′ may include amorphous silicon, low-temperature polycrystalline silicon (LTPS), metal oxide, other suitable materials, or a combination thereof. In this embodiment, the material of the semiconductor layer SE′ of the transistor TFT′ includes metal oxide, and the material of the semiconductor layer SE of the transistor TFT includes low-temperature polycrystalline silicon, but the disclosure is not limited thereto. In addition, in this embodiment, the transistor TFT′ is a bottom gate transistor structure, and the transistor TFT is a top gate transistor structure, but the disclosure is not limited thereto. In this embodiment, the source S′ and the drain D′ may be respectively electrically connected to the semiconductor layer SE′ through a hole VS' and a hole VD′ penetrating the insulation layer IL4, but the disclosure is not limited thereto.

The connection electrode CE1 is, for example, disposed on the insulation layer IL1 and may, for example, belong to the same layer as the gate G′ of the transistor TFT′. In this embodiment, the connection electrode CE1 may be electrically connected to the drain D of the transistor TFT through the opening IL3_OP of the insulation layer IL3, but the disclosure is not limited thereto. Although not shown in the drawings, the connection electrode CE1 may, for example, electrically connect the transistor TFT and the adjacent transistor TFT.

The connection electrode CE2 is, for example, disposed on the planar layer PL1 and may be electrically connected to the drain D′ of the transistor TFT′ through the opening PL1_OP of the planar layer PL1, but the disclosure is not limited thereto.

The planar layer PL3 is, for example, disposed on the planar layer PL1 and partially overlaps with the connection electrode CE2. From another perspective, the planar layer PL3 may, for example, include an opening PL3_OP that exposes a part of the connection electrode CE2, so that the first electrode E1 of the light-emitting structure LE may be electrically connected to the connection electrode CE2 through the opening PL3_OP, so that the light-emitting structure LE is electrically connected to the transistor TFT′. The material of the planar layer PL3 may be, for example, an organic material (such as polytetrafluoroethylene, polyimide, parylene, benzocyclobutene, or other suitable materials), but the disclosure is not limited thereto.

In this embodiment, the first opening PV1_OP1c of the insulation layer PV1′ is formed by performing two patterning processes. Therefore, the first opening PV1_OP1c may be in the form of overlapping with a pattern opening Tr1 and a pattern opening Tr2 in the cross-sectional view of the electronic device 10c, wherein the pattern opening Tr1 is located between the pattern opening Tr2 and the substrate SB.

Specifically, the outline of the first opening PV1_OP1c of the insulation layer PV1′ is, for example, defined by a side surface of the insulation layer IL4, a side surface of the insulation layer IL2, a part of a bottom surface of the insulation layer IL2, a side surface of the insulation layer IL3, a side surface of the insulation layer IL1, a side surface of the insulation layer GI, and the top surface of the buffer layer BF, wherein the side surface of the insulation layer IL4 is connected to the side surface of the insulation layer IL2, the side surface of the insulation layer IL2 is connected to the part of the bottom surface of the insulation layer IL2, the part of the bottom surface of the insulation layer IL2 is connected to the side surface of the insulation layer IL3, the side surface of the insulation layer IL3 is connected to the side surface of the insulation layer IL1, the side surface of the insulation layer IL1 is connected to the side surface of the insulation layer GI, and the side surface of the insulation layer GI is connected to the top surface of the buffer layer BF, but the disclosure is not limited thereto. In addition, in this embodiment, the insulation layer PV1′ may also include a second opening PV1_OP2c adjacent to the first opening PV1_OP1c, wherein the outline of the second opening PV1_OP2c of the insulation layer PV1′ may be the same as or similar to the outline of the first opening PV1_OP1c of the insulation layer PV1′, but the disclosure is not limited thereto. In some embodiments, the outline of the second opening PV1_OP2c and the outline of the first opening PV1_OP1c may include arc-shaped outlines, which may be used to account for the possibility of cracks forming during the formation process of the second opening PV1_OP2c and/or the first opening PV1_OP1c.

In some embodiments, the depth T3 of the first opening PV1_OP1c in the insulation layer PV1 may comply with the following relationship: 0.5 μm≤T3≤5 μm, but the disclosure is not limited thereto.

From another perspective, in the cross-sectional view of the electronic device 10c, the first opening PV1_OP1c of the insulation layer PV1′ includes a first width w11, a second width w12, and a third width w13 in the direction sd, wherein the third width w13 is between the first width w11 and the second width w12, and the second width w12 is closer to the substrate SB than the first width w11. Specifically, the first width w11 may, for example, be defined as the width of a bottom portion Tr2_B of the pattern opening Tr2 (for example, the distance between the adjacent insulation layers IL2 in the direction sd), the second width w12 may, for example, be defined as the width of a bottom portion Tr1_B of the pattern opening Tr1 (for example, the distance between the adjacent insulation layers GI in the direction sd), and the third width w13 may, for example, be defined as the width of a top portion Tr1_T of the pattern opening Tr1 (for example, the distance between the adjacent insulation layers IL3 in the direction sd). Consequently, in this embodiment, the third width w13 may be greater than the first width w11, and the third width w13 may be greater than the second width w12. In addition, in some embodiments, the first width w11, the second width w12, and the third width w13 of the first opening PV1_OP1c of the insulation layer PV1′ also comply with the following relationships: 0.1 μm≤w11≤15 μm, 0.1 μm≤w12≤15 μm, and 0.1 μm≤w13≤15 μm.

In this embodiment, by designing the first width w11, the second width w12, and the third width w13 of the first opening PV1_OP1c of the insulation layer PV1′ to comply with the above relationships, the electronic device 10c can be easily bent, the formation of cracks can be reduced, and there can be a relatively large element layout space. In contrast, when the first width w11, the second width w12, and the third width w13 of the first opening PV1_OP1c of the insulation layer PV1′ are less than 0.1 μm, the first opening PV1_OP1c may be difficult to form; and when the first width w11, the second width w12, and the third width w13 of the first opening PV1_OP1c of the insulation layer PV1′ are greater than 15 μm, the element layout space of the electronic device 10c is reduced.

FIG. 3B is a partial cross-sectional schematic view of a fourth embodiment according to a cross-section line A-A′ of FIG. 1A. It should be noted that the embodiment of FIG. 3B may use the reference numerals and part of the content of the embodiment of FIG. 3A, wherein the same or similar numerals are used to represent the same or similar elements, and descriptions of the same technical content are omitted.

Referring to FIG. 3B, the main differences between an electronic device 10d of this embodiment and the electronic device 10c are that: (1) a first organic portion Or1′ includes a curved surface; (2) some conductive lines in the electronic device 10d span a first opening PV1_OP1d of the insulation layer PV1′.

In this embodiment, after forming the insulation layer IL1 and before forming the gate G′ of the transistor TFT′, the organic portion Or11 is filled in a pattern opening Tr1′. The organic portion Or11 may be formed by, for example, a jet printing process, so a top surface thereof in the cross-sectional view of the electronic device 10d may be, for example, a curved surface. The curved surface design can reduce the stress on the current layer, but the disclosure is not limited thereto.

Thereafter, a first metal layer is formed on the insulation layer IL1, wherein the first metal layer may be located on the organic portion Or11. In other words, the first metal layer may, for example, span the first opening PV1_OP1d of the insulation layer PV1′, but the disclosure is not limited thereto. In this embodiment, the first metal layer includes the gate G′ partially overlapping with the semiconductor layer SE′ of the transistor TFT′.

In addition, in this embodiment, after forming the insulation layer IL4 and before forming the source S′ of the transistor TFT′, an organic portion Or12 is filled in a pattern opening Tr2′. The organic portion Or12 may be formed by, for example, a jet printing process, so a top surface thereof in the cross-sectional view of the electronic device 10d may be, for example, a curved surface. The curved surface design can reduce stress on the current layer, but the disclosure is not limited thereto.

Thereafter, a second metal layer is formed on the insulation layer ILA, wherein the second metal layer may be located on the organic portion Or12. In other words, the second metal layer may, for example, span the first opening PV1_OP1d of the insulation layer PV1′ to reduce the element layout space occupied in the electronic device 10d, but the disclosure is not limited thereto. In this embodiment, the second metal layer includes the source S′ electrically connected to the semiconductor layer SE′ of the transistor TFT′.

In this embodiment, the organic portion Or11 and the organic portion Or12 may be formed into the first organic portion Or1′, but the disclosure is not limited thereto.

In this embodiment, the first metal layer (including the gate G′ of the transistor TFT′) and the second metal layer (including the source S′ of the transistor TFT′) may also span a second opening PV1_OP2d of the insulation layer PV1′ to reduce the element layout space occupied in the electronic device 10d, but the disclosure is not limited thereto.

In some embodiments, a center line c3 of the pattern opening Tr1′ may be aligned with a center line c4 of the pattern opening Tr2′. Specifically, in the first opening PV1_OP1d of the insulation layer PV1′, the center line c3 of the pattern opening Tr1′ is, for example, aligned with the center line c4 of the pattern opening Tr2′ in the top view direction n of the substrate SB, wherein the “alignment” mentioned here may, for example, refer to overlapping in the top view direction n. By aligning the center line c3 of the pattern opening Tr1′ with the center line c4 of the pattern opening Tr2′, the element layout space occupied by the first opening PV1_OP1d in the electronic device 10d can be reduced, but this disclosure is not limited thereto. In other embodiments, the center line c3 of the pattern opening Tr1′ may not be aligned with the center line c4 of the pattern opening Tr2′. Specifically, in the second opening PV1_OP2d of the insulation layer PV1′, the center line c3 of the pattern opening Tr1′ is, for example, not aligned with the center line c4 of the pattern opening Tr2′ in the top view direction n of the substrate SB. By having the center line c3 of the pattern opening Tr1′ misaligned with the center line c4 of the pattern opening Tr2′, different cracks formed, for example, due to the stress of bending the electronic device 10d can be blocked.

FIG. 4 is a partial cross-sectional schematic view of a fifth embodiment according to a cross-section line A-A′ of FIG. 1A. It should be noted that the embodiment of FIG. 4 may use the reference numerals and part of the content of the embodiment of FIG. 3B, wherein the same or similar numerals are used to represent the same or similar elements, and the descriptions of the same technical content are omitted.

Referring to FIG. 4, the main difference between an electronic device 10e of this embodiment and the electronic device 10d is that: some conductive lines in the electronic device 10e may also be located in a first opening PV1_OP1e of the insulation layer PV1′.

In this embodiment, the first metal layer (including the gate G′ of the transistor TFT′) may be located in the first opening PV1_OP1e of the insulation layer PV1′ and may extend from the insulation layer IL1 through the first opening PV1_OP1e onto the adjacent the insulation layer IL1, but the disclosure is not limited thereto. In this embodiment, the electronic device 10e may further include a conductive layer MO, wherein the conductive layer MO is disposed between the substrate SB and the buffer layer BF and is exposed by a hole VG′. In this embodiment, the gate G1′ of a part of the transistor TFT′ and a metal element G2′ may be electrically connected to the conductive layer MO through the hole VG′. Consequently, the gate G1′ of a part of the transistor TFT′ and the metal element G2′ disposed on the adjacent insulation layer IL1 may be electrically connected to each other through the conductive layer MO.

In this embodiment, the electronic device 10d may further include a connection electrode CE2′, wherein the connection electrode CE2′ is electrically connected to the source S1′ of the transistor TFT′ and a metal element S2′ through the opening PL1_OP′ of the planar layer PL1, but the disclosure is not limited thereto. Consequently, the source S1′ and the metal element S2′ disposed on the adjacent planar layer PL1 may be electrically connected to each other through the connection electrode CE2′.

In some embodiments, the material of the first organic portion Or1 in the planar layer PL1 may include a light-shielding material to shield the gate G′ located in the first opening PV1_OP1e of the insulation layer PV1′, but the disclosure is not limited thereto.

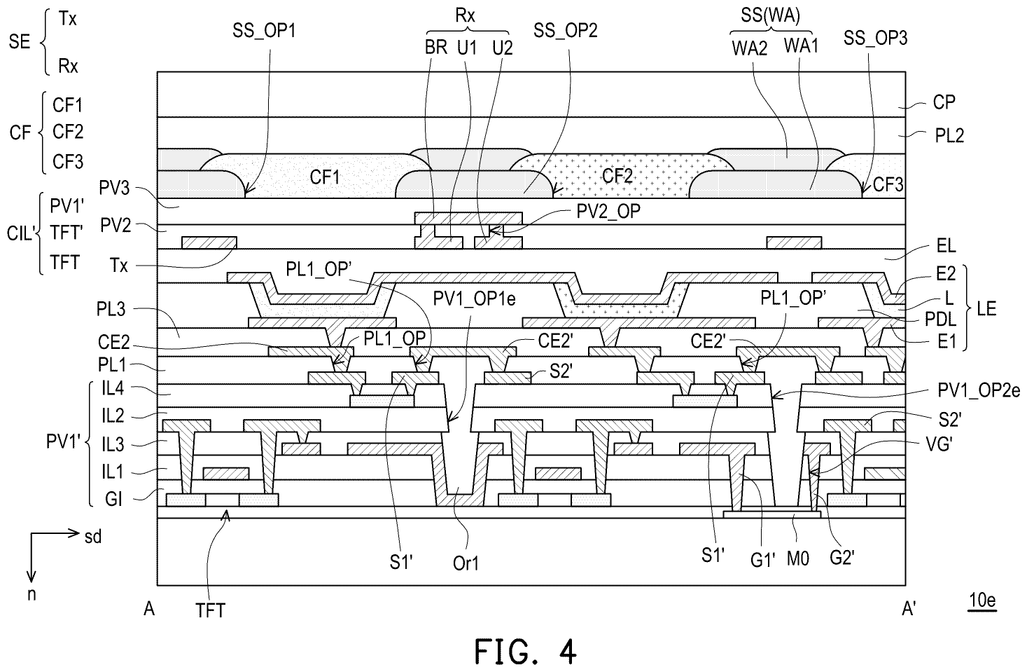

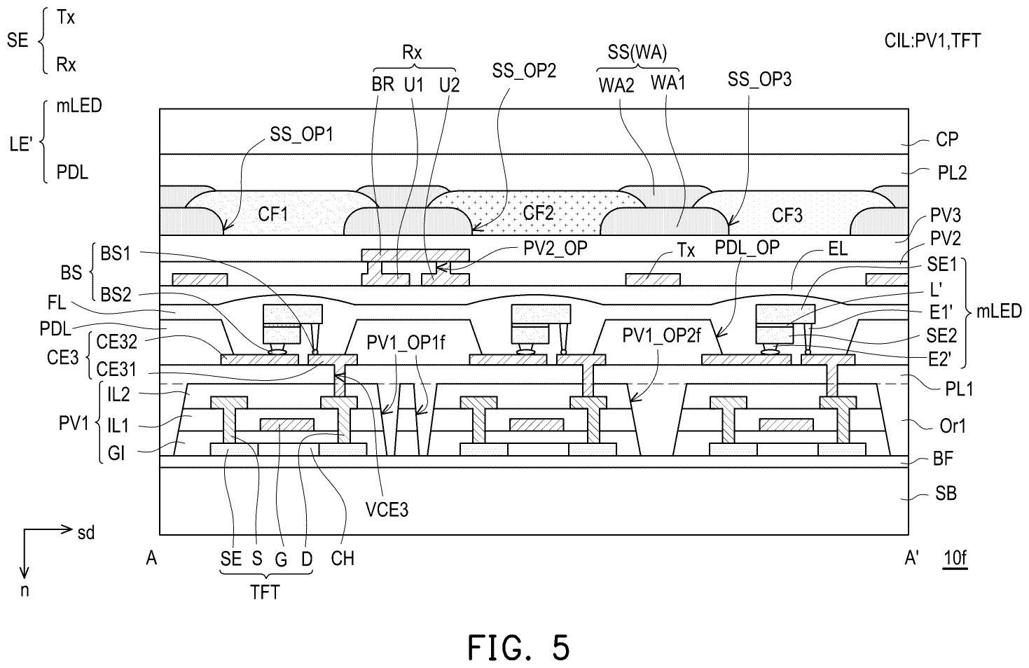

FIG. 5 is a partial cross-sectional schematic view of a sixth embodiment according to a cross-section line A-A′ of FIG. 1A. It should be noted that the embodiment of FIG. 5 may use the reference numerals and part of the content of the embodiment of FIGS. 1A and 1B, wherein the same or similar numerals are used to represent the same or similar elements, and descriptions of the same technical content are omitted.

Referring to FIG. 5, the main differences between an electronic device 10f of this embodiment and the electronic device 10a are that: (1) a light-emitting structure LE′ includes an inorganic light-emitting diode mLED; (2) one shielding structure SS overlaps with multiple first openings PV1_OP1f of the corresponding insulation layer PV1.

In this embodiment, the inorganic light-emitting diode mLED in the light-emitting structure LE′ may include a micro-light-emitting diode. For example, the light-emitting structure LE′ may be a flip-chip micro-light-emitting diode, but the disclosure is not limited thereto. Specifically, the inorganic light-emitting diode mLED may include a first semiconductor layer SE1, a second semiconductor layer SE2, a light-emitting layer L′, a first electrode E1′, and a second electrode E2′.

The first semiconductor layer SE1 and the second semiconductor layer SE2 may, for example, respectively include an N-type doped semiconductor and a P-type doped semiconductor or may respectively include a P-type doped semiconductor and an N-type doped semiconductor. The materials of the first semiconductor layer SE1 and the second semiconductor layer SE2 may include, for example, gallium nitride (GaN), indium gallium nitride (InGaN), gallium arsenide (GaAs), aluminum gallium indium phosphide (AlGaInP), other materials composed of group IIIA and group VA elements, or other suitable materials, but the disclosure is not limited thereto. The light-emitting layer L′ may, for example, have a quantum well (QW), which may be, for example, a single quantum well (SQW), a multiple quantum well (MQW), or other quantum wells. Consequently, the holes and electrons provided by the first semiconductor layer SE1 and the second semiconductor layer SE2 may be combined in the light-emitting layer L′ and emit light energy.

The first electrode E1′ and the second electrode E2′ may, for example, be respectively electrically connected to the first semiconductor layer SE1 and the second semiconductor layer SE2. In some embodiments, the first electrode E1′ may be connected to the drain D of the transistor TFT, so that the inorganic light-emitting diode mLED may be driven by the transistor TFT. The first electrode E1′ and the second electrode E2′ may, for example, include suitable conductive materials, but the disclosure is not limited thereto.

In this embodiment, the electronic device 10f may further include a connection electrode CE3 and a bonding structure BS.

The connection electrode CE3 is, for example, disposed on the planar layer PL1 and includes a connection electrode CE31 and a connection electrode CE32, wherein the connection electrode CE31 is electrically connected to the first electrode E1′, and the connection electrode CE32 is electrically connected to the second electrode E2′. In this embodiment, the connection electrode CE1 may be electrically connected to the drain D of the transistor TFT through a hole VCE3 penetrating the planar layer PL1 and the insulation layer IL2, but the disclosure is not limited thereto. The connection electrode CE3 may, for example, include a suitable conductive material, but the disclosure is not limited thereto.

The bonding structure BS is, for example, disposed on the connection electrode CE3 and includes a bonding structure BS1 and a bonding structure BS2, wherein the bonding structure BS1 is electrically connected to the first electrode E1′ and the connection electrode CE31, and the bonding structure BS2 is electrically connected to the second electrode E2′ and the connection electrode CE32, such that the inorganic light-emitting diode mLED may be electrically connected to the transistor TFT. The bonding structure BS may, for example, include a suitable conductive material, but the disclosure is not limited thereto.

In this embodiment, the electronic device 10f further includes a filling layer FL. The filling layer FL is, for example, disposed in the opening PDL_OP defined by the pixel definition layer PDL and is, for example, disposed adjacent to or surrounding the inorganic light-emitting diode mLED. The filling layer FL may, for example, be used to fix or protect the inorganic light-emitting diode mLED. In some embodiments, the filling layer FL may include a transparent material. For example, the material of the filling layer FL may include epoxy resin, acrylic, other suitable materials, or a combination thereof, but the disclosure is not limited thereto.

In this embodiment, one shielding structure SS may overlap with multiple first openings PV1_OP1f of the corresponding insulation layer PV1. Specifically, one shielding structure SS may, for example, overlap with the two first openings PV1_OP1f of the insulation layer PV1 in the top view direction of the substrate SB, but the disclosure is not limited thereto. From another perspective, multiple first openings PV1_OP1f may be formed between adjacent transistors, but the disclosure is not limited thereto. In this embodiment, one shielding structure SS may, for example, overlap with one second opening PV1_OP2f of the corresponding insulation layer PV1 in the top view direction n of the substrate SB.

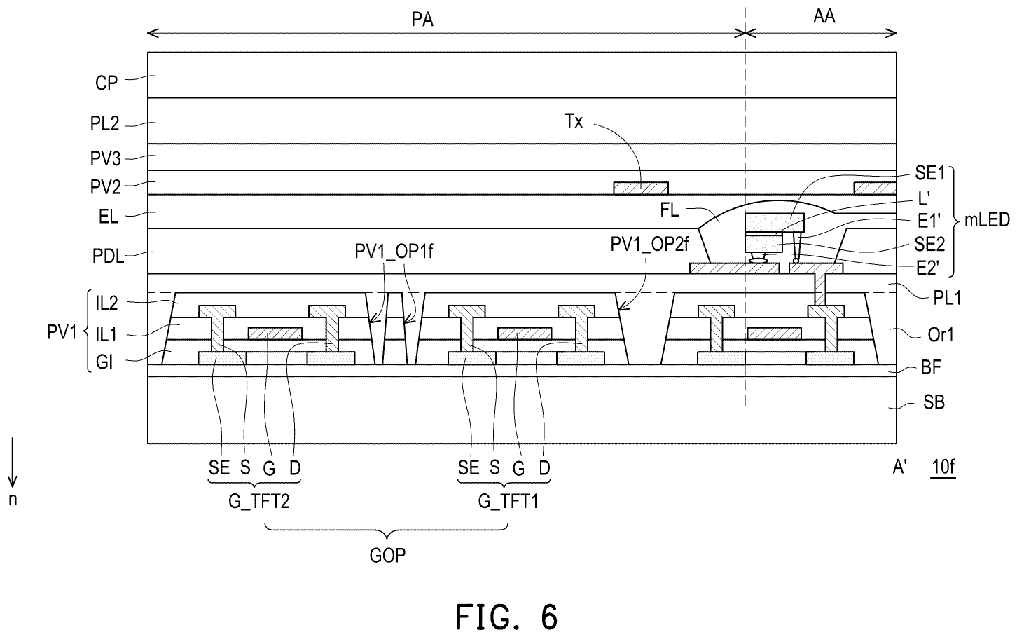

FIG. 6 shows a partial cross-sectional view of an embodiment of a peripheral area of the electronic device 10f of FIG. 5. It should be noted that the embodiment of FIG. 5 may use the reference numerals and part of the content of the embodiment of FIGS. 1A to 1B, wherein the same or similar numerals are used to represent the same or similar elements, and descriptions of the same technical content are omitted.

Referring to FIG. 6, a gate driver on panel GOP is disposed in a peripheral area PA of the electronic device 10f, wherein the structure of the gate driver on panel GOP may be, for example, the same as or similar to the structure of the circuit structure CIL located in an active area AA, and the gate driver on panel GOP may, for example, be disposed on at least one side of the active area AA, but the disclosure is not limited thereto.

The gate driver on panel GOP includes, for example, a transistor G_TFT1 and a transistor G_TFT2. The transistor G_TFT1 and the transistor G_TFT2 are adjacent to each other, and the transistor G_TFT1 is closer to the active area AA of the electronic device 10f than the transistor G_TFT2, but the disclosure is not limited thereto.

In some embodiments, multiple first openings PV1_OP1f may also be disposed between the transistor G_TFT1 and the transistor G_TFT2. In this embodiment, two first openings PV1_OP1f are also disposed between the transistor G_TFT1 and the transistor G_TFT2, but the disclosure is not limited thereto.

In this embodiment, one first opening PV1_OP1f is disposed between the transistor G_TFT1 and the transistor TFT located in the active area AA, but the disclosure is not limited thereto.

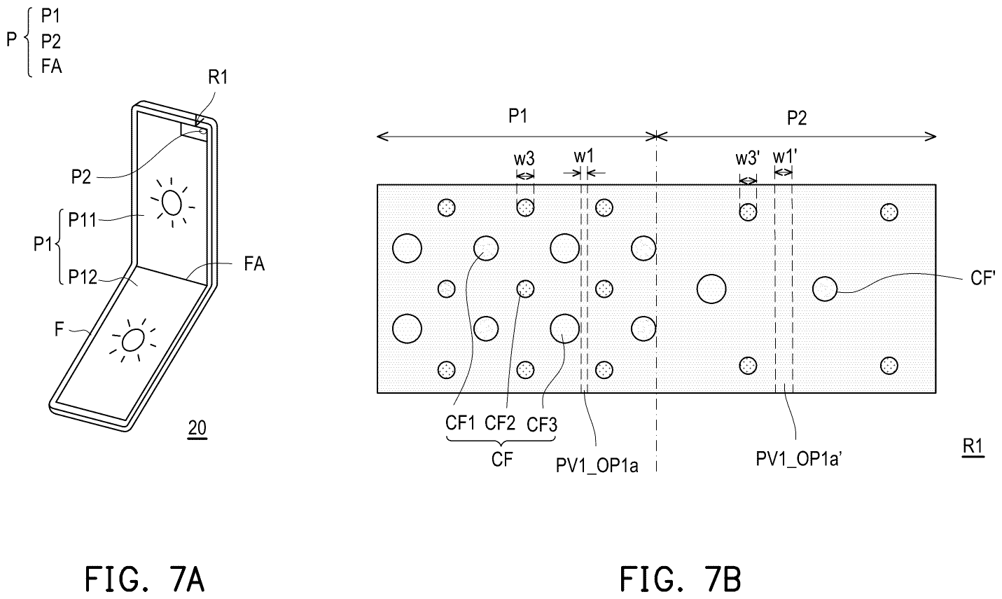

FIG. 7A is a three-dimensional schematic view of an electronic device according to an embodiment of the disclosure, and FIG. 7B is a partially enlarged top schematic view of an embodiment in a region R1 of FIG. 7A. It should be noted that the embodiment of FIG. 7B may use the reference numerals and part of the content of the embodiment of FIG. 1A, wherein the same or similar numerals are used to represent the same or similar elements, and descriptions of the same technical content are omitted.

Referring to FIG. 7A, an electronic device 20 of this embodiment is a foldable electronic device, specifically a foldable mobile phone. In this embodiment, the electronic device 20 includes a display panel P and a frame F.

The display panel P includes, for example, a display area P1 and a camera area P2 located at the edge of the display panel P, wherein the display area P1 may, for example, be used to display an image, and the camera area P2 may, for example, be used to capture an external scene and may also be used to display an image. In this embodiment, the display panel P further includes a bending axis FA, wherein the electronic device 20 may be folded relative to the bending axis FA. In some embodiments, when the electronic device 20 is folded, the display area P1 may include a display area P11 and a display area P12 separated by the bending axis FA, wherein a display surface of the display area P11 and a display surface of the display area P12 may respectively face different directions.

In some embodiments, the display area P1 may include a keyboard (not shown), which may, for example, be operated by the user and provide a corresponding command signal to a processor (not shown) in the electronic device 20 after the operation. The processor may, for example, cause the display panel P to display an image or update an image based on the command signal.

The frame F, for example, surrounds the display panel P and is combined with the display panel P, but the disclosure is not limited thereto.

Referring to FIG. 7B, the configurations of the optical unit CF and the first opening PV1_OP1a of the insulation layer PV1 in the display area P1 and the configurations of an optical unit CF′ and the first opening PV1_OP1a of the insulation layer PV1 in the camera area P2 are respectively shown in the region R1.

In this embodiment, considering that the contrast in the camera area P2 may be smaller relative to the contrast in the display area P1, the size of the optical unit CF′ located in the camera area P2 may be greater than the size of the optical unit CF located in the display area P1. In other words, a width w3′ of the optical unit CF′ located in the camera area P2 in the direction sd may, for example, be greater than the width w3 of the optical unit CF located in the display area P1 in the direction sd.

In addition, in this embodiment, considering that the contrast in the camera area P2 may be smaller than the contrast in the display area P1, the distance between adjacent optical units CF′ located in the camera area P2 may be greater than the distance between adjacent optical units CF located in the display area P1. Consequently, the size of the first opening PV1_OP1a′ disposed in the camera area P2 may be greater relative to the size of the first opening PV1_OP1a disposed in the display area P1. In other words, a width w1′ of the first opening PV1_OP1a′ located in the camera area P2 may, for example, be greater than the width w1 of the first opening PV1_OP1a located in the display area P1.

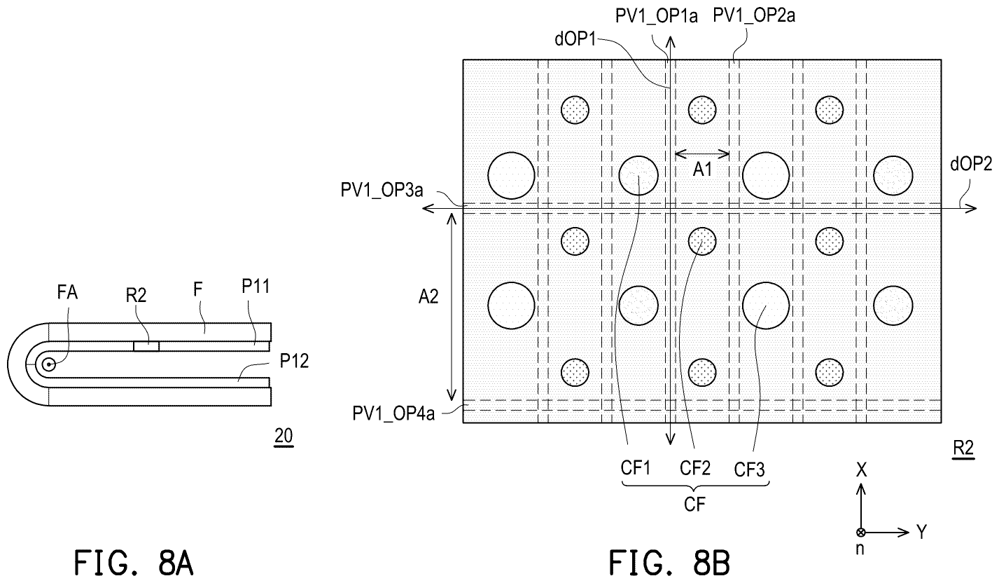

FIG. 8A shows a three-dimensional schematic view of the folded electronic device 20 of FIG. 7A, and FIG. 8B is a partially enlarged top schematic view of an embodiment in a region R2 of FIG. 8A. It is worth noting that the state of the “folded” electronic device 20 shown in FIG. 8A may include a state in which the display surface of the display area P11 faces the display surface of the display area P12 and/or a state in which the electronic device 20 cannot be folded anymore.

In this embodiment, in the region R2, the insulation layer PV1 includes the first opening PV1_OP1a, the second opening PV1_OP2a, a third opening PV1_OP3a, and a fourth opening PV1_OP4a, wherein the first opening PV1_OP1a is adjacent to the second opening PV1_OP2a, and the third opening PV1_OP3a is adjacent to the fourth opening PV1_OP4a.

In some embodiments, the first opening PV1_OP1a and the second opening PV1_OP2a have a first extension direction dOP1, and the third opening PV1_OP3a and the fourth opening PV1_OP4a have a second extension direction dOP2, wherein an extension direction of the bending axis FA is the same as the first extension direction dOP1. In this embodiment, the distance between the first opening PV1_OP1a and the second opening PV1_OP2a is different from the distance between the third opening PV1_OP3a and the fourth opening PV1_OP4a. From another perspective, the density of the first opening PV1_OP1a and the second opening PV1_OP2a in the electronic device 20 is different from the density of the third opening PV1_OP3a and the fourth opening PV1_OP4a. In other words, the number of the first openings PV1_OP1a and the second openings PV1_OP2a in the same cross-sectional area is greater than the number of the third openings PV1_OP3a and the fourth openings PV1_OP4a in the same cross-sectional area.

Specifically, a distance A1 between the first opening PV1_OP1a and the second opening PV1_OP2a in the second extension direction dOP2 is smaller than a distance A2 between the third opening PV1_OP3a and the fourth opening PV1_OP4a in the first extension direction dOP1. In other words, the density of the first opening PV1_OP1a and the second opening PV1_OP2a in the electronic device 20 is greater than the density of the third opening PV1_OP3a and the fourth opening PV1_OP4a.

Through the above design, the extension direction of the bending axis FA is the same as the first extension direction dOP1 of the denser first opening PV1_OP1a and second opening PV1_OP2a. When the electronic device 20 is folded, the possibility of the inorganic film layer (for example, the insulation layer in the circuit structure CIL) cracking can be further reduced. In other embodiments, the number of the first openings PV1_OP1a and the second openings PV1_OP2a formed in the electronic device 20 may be increased without forming the third opening PV1_OP3a and the fourth opening PV1_OP4a, but the disclosure is not limited thereto.

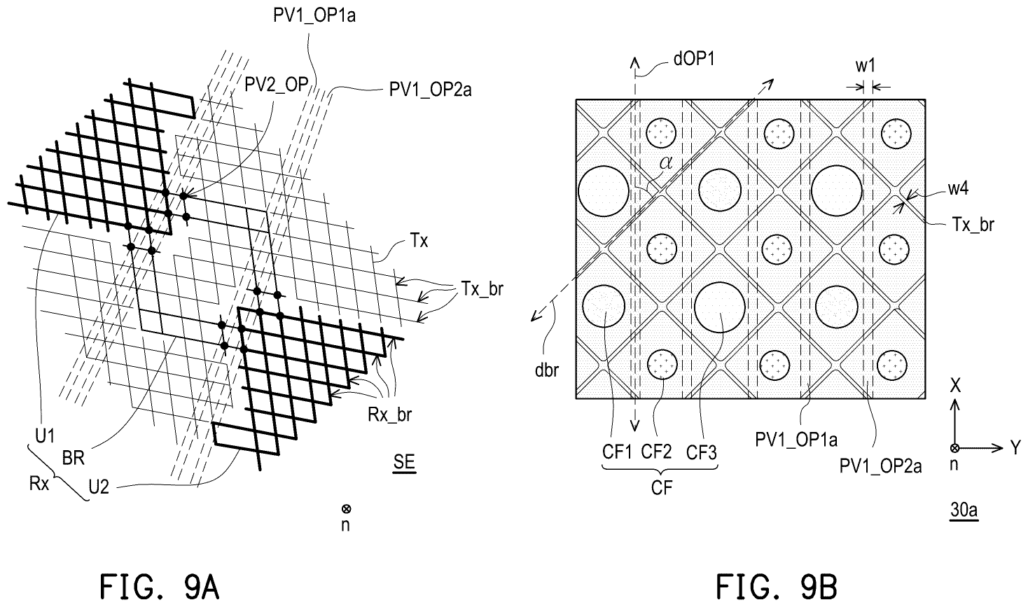

FIG. 9A is a partial top schematic view of an arrangement relationship between a sensing structure and a first opening of an insulation layer in an electronic device according to an embodiment of the disclosure, and FIG. 9B is a partial top schematic view of an arrangement relationship between a sensing structure, a first opening of an insulation layer, and an optical unit in an electronic device according to a first embodiment of the disclosure. It should be noted that the embodiments of FIG. 9A and FIG. 9B may use the reference numerals and part of the content of the embodiment of FIG. 1A to FIG. 1B, wherein the same or similar numerals are used to represent the same or similar elements, and descriptions of the same technical content are omitted.

Referring to FIG. 9A and FIG. 9B simultaneously, the sensing structure SE in an electronic device 30a of this embodiment includes a sensing electrode Rx and a driving electrode Tx, wherein the sensing electrode Rx has a first unit U1, a second unit U2, and a bridging portion BR for electrically connecting the first unit U1 and the second unit U2, but the disclosure is not limited thereto. As described in the above embodiments, the first unit U1 and the second unit U2 may be respectively electrically connected to the bridging portion BR, for example, through the opening PV2_OP of the insulation layer PV2 (exposing the first unit U1 and the second unit U2). In this embodiment, the sensing electrode Rx includes multiple branch portions Rx_br, and the driving electrode Tx includes multiple branch portions Tx_br.

The sensing structure SE, for example, partially overlaps with the first opening PV1_OP1a of the insulation layer PV1. Specifically, the bridging portion BR of the sensing structure SE may, for example, at least partially overlap with the first opening PV1_OP1a of the insulation layer PV1; or the sensing electrode Rx and/or the driving electrode Tx of the sensing structure SE may, for example, partially overlap with the first opening PV1_OP1a of the insulation layer PV1, but the disclosure is not limited thereto. In some embodiments, in the top view of the electronic device 30a, an included angle α between an extension direction dbr of the branch portion Rx_br of the sensing electrode Rx and/or the branch portion Tx_br of the driving electrode Tx of the sensing structure SE and the extension directions dOP1 of the first opening PV1_OP1a of the insulation layer PV1 is greater than or equal to 30° to less than or equal to 50°.

In this embodiment, in the top view of the electronic device 30a, the first opening PV1_OP1a of the insulation layer PV1 has a width w1, the branch portion Tx_br (or the branch portion Rx_br) of the sensing structure SE has a width w4, and the width w1 of the first opening PV1_OP1a of the insulation layer PV1 and the width w4 of the branch portion Tx_br (or the branch portion Rx_br) satisfy the following relationship: 0.5≤w1/w4≤2.

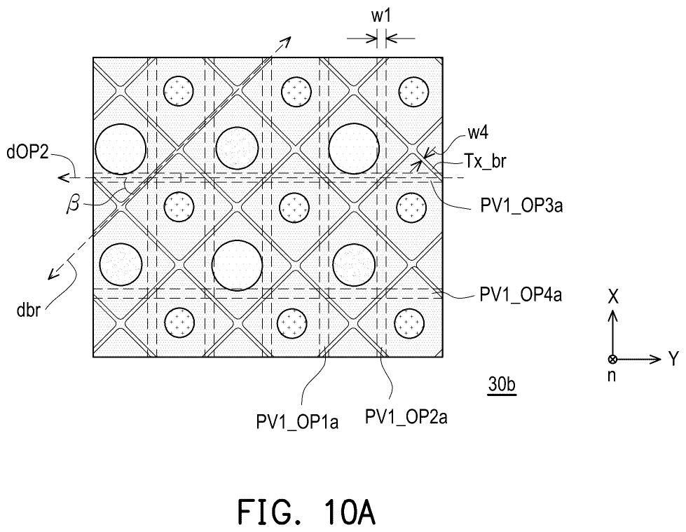

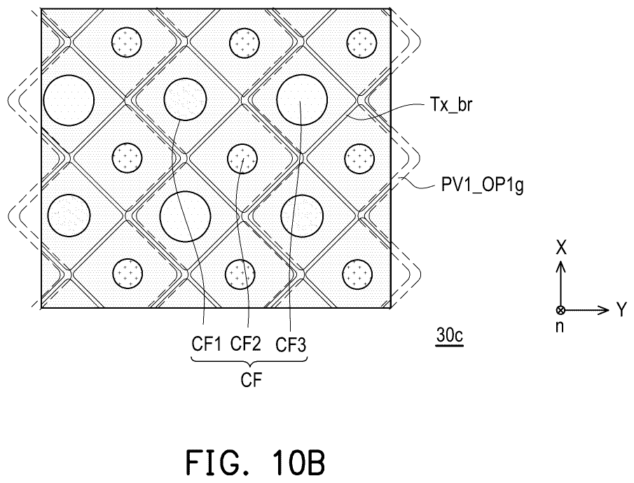

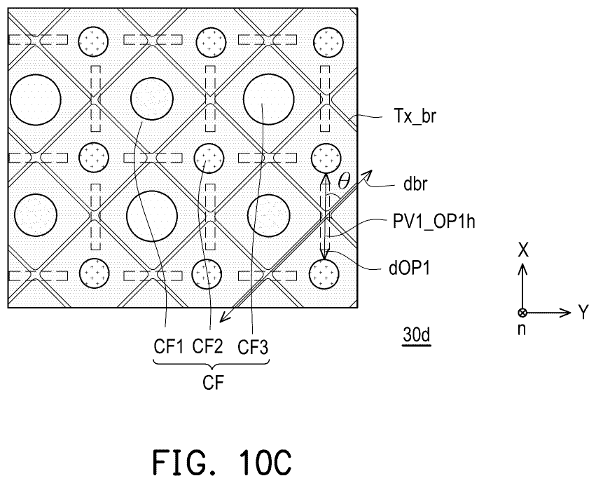

FIG. 10A is a partial top schematic view of an arrangement relationship between a sensing structure, a first opening of an insulation layer, and an optical unit in an electronic device according to a second embodiment of the disclosure, FIG. 10B is a partial top schematic view of an arrangement relationship between a sensing structure, a first opening of an insulation layer, and an optical unit of an electronic device according to a third embodiment of the disclosure, and FIG. 10C is a partial top schematic view of an arrangement relationship between a sensing structure, a first opening of an insulation layer, and an optical unit in an electronic device according to a fourth embodiment of the disclosure. It should be noted that the embodiments of FIGS. 10A to 10C may use the reference numerals and part of the content of the embodiment of FIG. 9B, wherein the same or similar numerals are used to represent the same or similar elements, and descriptions of the same technical content are omitted.

Referring to FIG. 10A, the insulation layer PV1 in the electronic device 30b of this embodiment also includes a third opening PV1_OP3a and a fourth opening PV1_OP4a, wherein the third opening PV1_OP3a is adjacent to the fourth opening PV1_OP4a.

In some embodiments, the first opening PV1_OP1a and the second opening PV1_OP2a have a first extension direction dOP1, and the third opening PV1_OP3a and the fourth opening PV1_OP4a have a second extension direction dOP2, wherein the second extension direction dOP2 may be parallel to the direction Y, but the disclosure is not limited thereto. In this embodiment, the distance between the first opening PV1_OP1a and the second opening PV1_OP2a is different from the distance between the third opening PV1_OP3a and the fourth opening PV1_OP4a. From another perspective, the density of the first opening PV1_OP1a and the second opening PV1_OP2a in the electronic device 30b is different from the density of the third opening PV1_OP3a and the fourth opening PV1_OP4a. In other words, the number of the first openings PV1_OP1a and the second openings PV1_OP2a in the same cross-sectional area is greater than the number of the third openings PV1_OP3a and the fourth openings PV1_OP4a in the same cross-sectional area.

In this embodiment, in the top view of the electronic device 30b, an included angle between the extension direction dbr of the branch portion Rx_br of the sensing electrode Rx and/or the branch portion Tx_br of the driving electrode Tx of the sensing structure SE and the extension direction dOP2 of the third opening PV1_OP3a (or the fourth opening PV1_OP4a) of the insulation layer PV1 is greater than or equal to 30° to less than or equal to 50°.

Referring to FIG. 10B, a first opening PV1_OP1g included in the insulation layer PV1 in the electronic device 30c of this embodiment has a wavy form, wherein the wavy first opening PV1_OP1g may periodically undulate along the direction X. Specifically, the first opening PV1_OP1g of the insulation layer PV1 overlaps with the branch portion Rx_br of the sensing electrode Rx and/or the branch portion Tx_br of the driving electrode Tx in the top view direction n of the substrate SB, such that the first opening PV1_OP1g of the insulation layer PV1 presents a wavy form in the top view of the electronic device 30c.

Referring to FIG. 10C, a first opening PV1_OP1h included in the insulation layer PV1 in the electronic device 30d of this embodiment has a segmented form. Specifically, one first opening PV1_OP1h of the insulation layer PV1 may extend from one first optical unit CF1 to another adjacent first optical unit CF1, so multiple segmented first openings PV1_OP1h may be formed, wherein an included angle Θ between the extension direction dbr of the branch portion Rx_br of the sensing electrode Rx and/or the branch portion Tx_br of the driving electrode Tx of the sensing structure SE and the extension direction dOP1 of the first opening PV1_OP1h of the insulation layer PV1 may be greater than or equal to 30° to less than or equal to 50°.

In summary, in the electronic device provided by some embodiments of the disclosure, the anti-reflection layer (the shielding structure) is disposed inside the electronic device to reduce the possibility of the shielding structure peeling off, which can improve the reliability of the electronic device.

In the electronic device provided by other embodiments of the disclosure, multiple openings extending along a direction are disposed in the insulation layer of the electronic device to isolate the driving elements in the circuit structure. When one or more insulation layers form cracks due to factors such as bending, at least one of the openings in the insulation layer may block the extension path of the cracks, thereby reducing the possibility of most of the driving elements being invaded by external moisture to improve the reliability of the electronic device.

In the electronic device provided by some embodiments of the disclosure, when the electronic device is bent, stress due to the bending of the electronic device can be reduced through the design of overlapping the shielding structure and the openings of the insulation layer, and as the shielding structure may not be easily peeled off, the reliability of the electronic device can be further improved. Furthermore, when the electronic device is operating, uneven brightness, dark lines, and/or other optical defects that may be caused by the formation of the openings in the insulation layer can be shielded by the shielding structure, so that the electronic device can have good display effects.

What is claimed is:

1. An electronic device, comprising:
a substrate,
an insulation layer, disposed on the substrate and comprising a first opening
a first organic portion, disposed in the first opening of the insulation layer,
a shielding structure, disposed on the insulation layer and comprising a retaining wall and a first opening, and
a first optical unit, disposed in the first opening of the shielding structure,
wherein the retaining wall of the shielding structure overlaps with the first opening of the insulation layer.

2. The electronic device of claim 1, wherein a width of the retaining wall of the shielding structure is greater than or equal to a width of the first opening of the insulation layer in a direction.

3. The electronic device of claim 2, wherein the width of the retaining wall of the shielding structure and the width of the first opening of the insulation layer satisfy a following relationship:
$$1 \leq w 2 / w 1 \leq 150 ,$$
wherein w1 is the width of the first opening of the insulation layer, and w2 is the width of the retaining wall of the shielding structure.

4. The electronic device of claim 1, wherein there is a distance between a center line of the first opening of the shielding structure and a center line of the first opening of the shielding structure in a cross-sectional view of the electronic device, and the distance satisfies a following relationship:
$$0 μm \leq d 1 \leq 10 μm ,$$
wherein d1 is the distance.

5. The electronic device of claim 1, wherein a width of the first optical unit is greater than or equal to a width of the first opening of the insulation layer in a direction.

6. The electronic device of claim 5, wherein the width of the first optical unit and the width of the first opening of the insulation layer satisfy a following relationship:
$$1 < w 3 / w 1 \leq 200 ,$$
wherein w1 is the width of the first opening of the insulation layer, and w3 is the width of the first optical unit.

7. The electronic device of claim 1, further comprising a second optical unit, wherein the shielding structure comprises a second opening, the retaining wall of the shielding structure is disposed between the first opening of the shielding structure and the second opening of the shielding structure, the second optical unit is disposed in the second opening of the shielding structure, the insulation layer comprises a second opening adjacent to the first opening of the insulation layer, and the retaining wall of the shielding structure overlaps with the second opening of the insulation layer.

8. The electronic device according to claim 1, wherein the insulation layer comprises a second opening, a third opening, and a fourth opening,
the first opening of the insulation layer is adjacent to the second opening of the insulation layer, and the first opening of the insulation layer and the second opening of the insulation layer have a first extension direction,
the third opening of the insulation layer is adjacent to the fourth opening of the insulation layer, the third opening of the insulation layer and the fourth opening of the insulation layer have a second extension direction, and the first extension direction is different from the second extension direction,
wherein a distance between the first opening of the insulation layer and the second opening of the insulation layer is different from a distance between the third opening of the insulation layer and the fourth opening of the insulation layer in a top view of the electronic device.

9. The electronic device of claim 1, wherein the first organic portion comprises a curved surface.

10. The electronic device of claim 1, wherein a material of the first organic portion comprises a light-shielding material.

11. The electronic device of claim 1, wherein the first opening of the insulation layer comprises a first width, a second width, and a third width in a cross-sectional view of the electronic device, the third width is between the first width and the second width, the second width is closer to the substrate than the first width, the third width is greater than the first width, and the third width is greater than the second width.

12. The electronic device of claim 1, further comprising a conductive line, wherein the conductive line is disposed on the substrate and spans the first opening of the insulation layer.

13. The electronic device of claim 1, further comprising a conductive line, wherein the conductive line is disposed on the substrate and is located in the first opening of the insulation layer.

14. The electronic device of claim 1, further comprising a sensing structure, wherein the sensing structure is disposed on the insulation layer and partially overlaps with the first opening of the insulation layer,
wherein in a top view of the electronic device, the first opening of the insulation layer has a width, a branch portion of the sensing structure has a width, and the width of the first opening of the insulation layer and the width of the branch portion of the sensing structure satisfy a following relationship:
$$0.5 \leq w 1 / w 4 \leq 2 ,$$
wherein w1 is the width of the first opening of the insulation layer, and w4 is the width of the branch portion of the sensing structure.

15. The electronic device of claim 1, further comprising a sensing structure, wherein the sensing structure is disposed on the insulation layer and partially overlaps with the first opening of the insulation layer,
wherein in a top view of the electronic device, an included angle between a branch portion of the sensing structure and a first extension direction of the first opening of the insulation layer is greater than or equal to 30° to less than or equal to 50°.

16. The electronic device of claim 1, further comprising a sensing structure, wherein the sensing structure is disposed on the insulation layer and comprises a first unit, a second unit, and a bridging portion, wherein the bridging portion connects the first unit and the second unit, and the bridging at least partially overlaps with the first opening of the insulation layer.
